(19) United States
(12) Patent Application Publication
(10) Pub. No.: US 2019/0269034 A1
(43) Pub. Date: Aug. 29, 2019

(54) VAPOR CHAMBER

(71) Applicant: Microsoft Technology Licensing, LLC, Redmond, WA (US)

(72) Inventor: Gavin D. STANLEY, Puyallup, WA (US)

(73) Assignee: Microsoft Technology Licensing, LLC, Redmond, WA (US)

(21) Appl. No.: 15/908,416

(22) Filed: Feb. 28, 2018

(51) Int. Cl. H05K 7/20; G06F 1/20; H01L 23/46

(52) U.S. Cl. CPC H05K 7/20309; H01L 23/46; G06F 1/203

(57) ABSTRACT

The description relates to thermal management of devices, such as computing devices. One example can include a vapor chamber that includes an evaporative region and a condensing region that are connected by a neck region that facilitates fluid flow along a fluid pathway. The neck region has a lesser width and a greater height when viewed transverse the fluid pathway than both the evaporative region and condensing region.

### BRIEF DESCRIPTION OF THE DRAWINGS

The accompanying drawings illustrate implementations of the concepts conveyed in the present document. Features of the illustrated implementations can be more readily understood by reference to the following description taken in conjunction with the accompanying drawings. Like reference numbers in the various drawings are used wherever feasible to indicate like elements. Further, the left-most numeral of each reference number conveys the FIG. and associated discussion where the reference number is first introduced.

FIG. 1A is a partial cutaway perspective view of an example device that can include the present constraint-accommodating vapor chamber implementations in accordance with the present concepts.

FIGS. 1B, 2, 3, 4A, 4B, 5, and 6 are perspective views of example constraint-accommodating vapor chambers in accordance with some implementations of the present concepts.

### DESCRIPTION

The present concepts relate to devices, such as computing devices. For many form factors, such as tablets, notebooks, and/or wearable devices, such as headsets, consumer preferences are toward smaller form factors, especially thinner and/or lighter form factors. At the same time, consumers want high performance from computing resources, such as processing resources, memory resources, etc. of the devices. The high performance tends to result in unwanted heat generation from the computing resources. This heat can be efficiently dispersed with vapor chambers. However, various components in the thin device can constrain possible routes and/or dimensions of the vapor chamber to the point of impeding fluid flow (and hence energy transfer) within the vapor chamber. The present concepts relating to vapor chamber design allow energy transfer to be maintained in these constrained devices via constraint-accommodating vapor chambers.

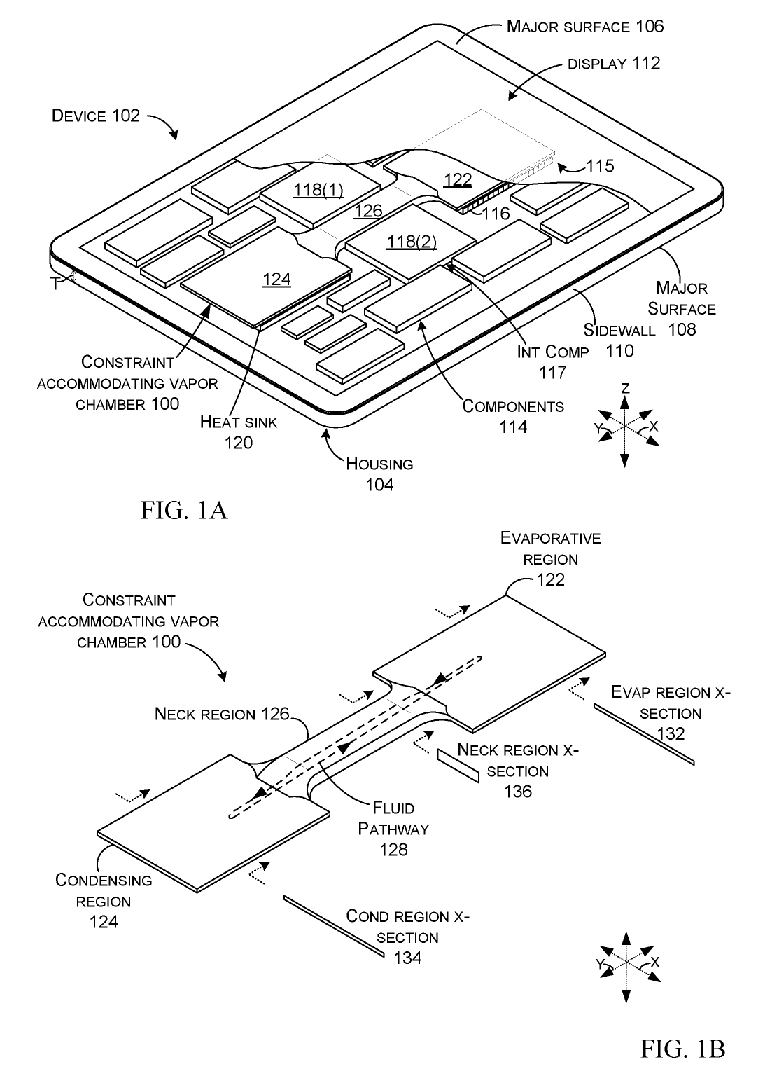

FIGS. 1A and 1B collectively show an example constraint-accommodating vapor chamber 100. FIG. 1A shows a partial cut-away view of an example device 102 that includes the constraint-accommodating vapor chamber 100. FIG. 1B shows the constraint-accommodating vapor chamber 100 in isolation.

In this case, the device 102 is manifest as a tablet type computing device. In this manifestation, device 102 can include a housing 104. In this example, the housing defines two opposing major surfaces 106 and 108 (facing the reader and facing away from the reader, respectively). A sidewall 110 can extend between the two major surfaces. In this example, a display 112 is positioned on first major surface 106. In some cases, the housing can be viewed as a bucket upon which the display is positioned during assembly.

Various components 114 can be positioned in the device between the two major surfaces. Some of these components 114 can be heat generating components 115 that generate enough heat that component damage can occur without thermal management. For instance, these heat generating components 115 can include a processor 116, such as CPUs and/or GPUs that tend to require thermal management. Other components 114, can be termed intervening components 117 that limit paths available for moving thermal energy away from the heat generating components 115. In this example, batteries 118 are examples of intervening components 117.

The constraint-accommodating vapor chamber 100 can transfer heat (e.g., thermal energy) from the heat generating components 115 to other regions of the device 102, such as to a heat sink 120. The constraint-accommodating vapor chamber 100 can include an evaporative region 122 that is fluidly coupled to a condensing region 124 by a neck region 126. The evaporative region 122 can be positioned proximate to (e.g., against) the heat generating component 115 to receive heat from the heat generating component. The condensing region 124 can be positioned proximate to the heat sink 120.

As mentioned above, market forces tend to drive a thickness or height T of the device 102 between the two major surfaces 106 and 108 to be as thin as possible. Also, market forces drive competing high performance expectations from the device. For instance, market forces demand top processing speeds and long battery life. Thus, processor 116 tends to generate large amounts of heat that needs to be managed, and components 114, such as batteries 118, need to be large and occupy a substantial portion of the available volume defined between the first and second major surfaces 106 and 108 and the sidewall 110. The constraint-accommodating vapor chamber 100 can accomplish this heat management despite the limited physical space in the device. For instance, in the illustrated configuration, neck region 126 is constrained in the x-reference direction by batteries 118(1) and 118(2) and thus is narrower in the x-reference direction than the evaporative region 122 and the condensing region 124. Stated another way, batteries 118 (and/or other intervening components 117) occupy nearly all of the thickness available between the major surfaces 106 and 108 such that the neck region 126 of constraint-accommodating vapor chamber 100 cannot extend over the batteries. As a result, available space for the neck region 126 is constrained between the batteries 118(1) and 118(2).

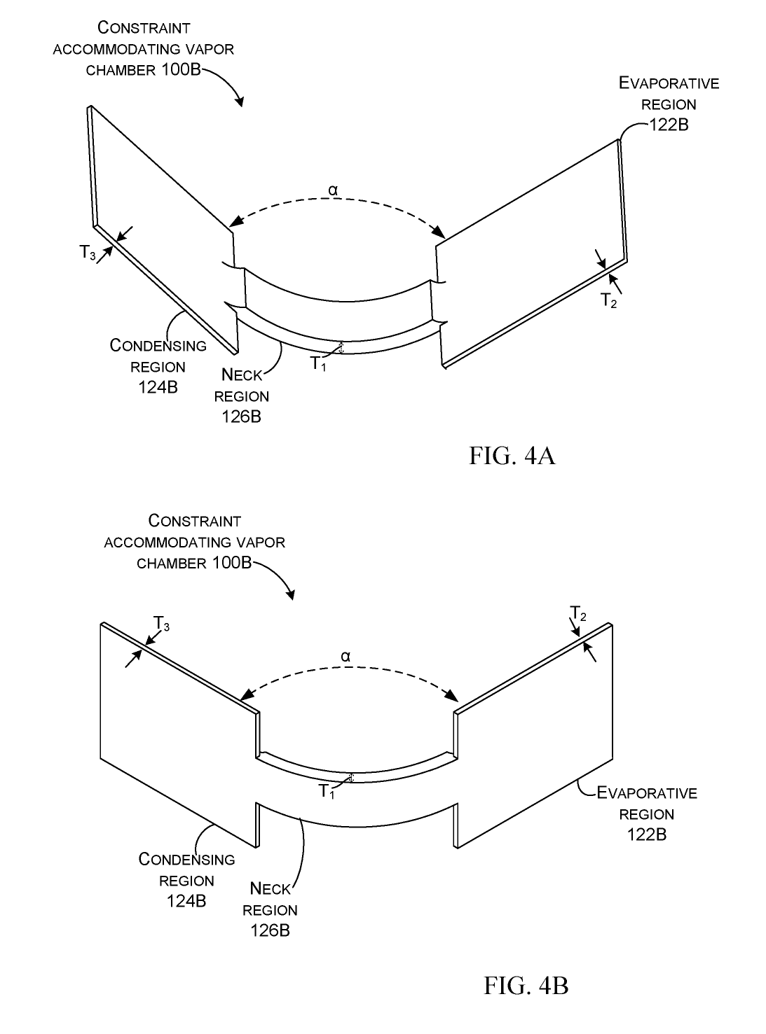

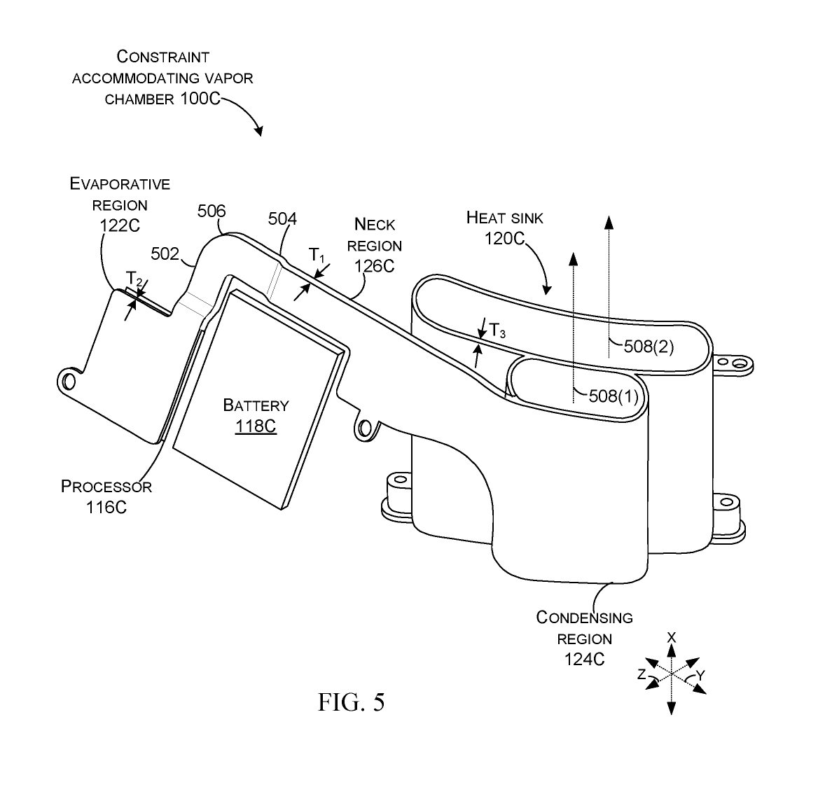

In this case, the evaporative region 122 and the condensing region 124 are both planar and lie in a common plane that extends parallel to the xy-reference plane between the major surfaces 106 and 108. Intervening components 117, such as batteries 118 in this example, can extend across a plane defined by the heat generating component 115 between the major surfaces 106 and 108 and limit paths available for the neck region 126. Alternative non-planar configurations are described below relative to FIGS. 4A-5.

Vapor chambers, such as constraint-accommodating vapor chamber 100 are sealed and contain a fluid, such as water or alcohol. To effectively transfer heat from the evaporative region 122 through the neck region 126 to the condensing region 124, the fluid travels along a recycling fluid pathway 128. Starting at the evaporative region 122, fluid in the liquid phase absorbs heat energy and evaporates (e.g., phase changes to a gas phase). The gas phase fluid travels out of the evaporative region 122 into the neck region 126 and into the condensing region 124. The condensing region 124 can be positioned proximate to the heat sink (120, FIG. 1A). The heat sink may be a physical structure, such as a component and/or the housing and/or the heat sink may be an air space. Heat loss from the condensing region 124 to the heat sink can cause the fluid to undergo another phase change back to a liquid form. The liquid form travels through the neck region 126 back to the evaporative region 122 where the process begins again. The liquid form tends to move along inner surfaces of the constraint-accommodating vapor chamber 100 via capillary action.

Various treatments can be applied to these inner surfaces to promote capillary flow, especially the lower inner surfaces (e.g., proximate to the heat generating component 115). For instance, textures, such as grooves, can be added to the inner surfaces, such as with a laser.

Alternatively, coatings, such as sintered powders, can be applied to the inner surfaces that increase adhesion properties and thus capillary flow. In still another option, screens can be used to increase capillary action. In some cases, inner walls may be created that run parallel to the fluid pathway and provide structural support to keep the vapor chamber from deforming. These inner walls can provide additional surface area that supports capillary action.

In contrast to the liquid phase fluid, the gas phase fluid traveling from the evaporative region 122 toward the condensing region 124 tends to flow in the open area defined between the inner surfaces. If the vapor chamber does not provide enough area along the fluid pathway 128, the counter flowing fluids can block one another and flood the area thereby restricting efficient countercurrent flow along the fluid pathway. This blockage can greatly reduce heat transfer and can result in failure of the device.

The illustrated implementations can avoid blockage by maintaining a cross-sectional area along the fluid pathway 128. An evaporative region cross-section is indicated at 132, a condensing region cross-section is indicated at 134, and a neck region cross-section is indicated at 136. As mentioned, the neck region 126 is constrained in the x-reference direction (e.g., neck region cross-section 136 is narrower (less wide) than evaporative region cross-section 132 and condensing region cross-section 134). To compensate for the lesser width, a height of the neck region is increased to maintain sufficient cross-sectional area. Stated another way, a cross-sectional profile of the neck region can be taller than the cross-sectional profiles of the evaporative region and the condensing region.

Note, in this case, the width of the neck region cross-section 136 is about ⅓ of the widths of the evaporative region cross-section 132 and condensing region cross-section 134, but the height is about three times greater than the height of evaporative region cross-section 132 and condensing region cross-section 134. This compensation can allow the present implementation to avoid a bottleneck in the neck region 126 that would impede fluid flow along the fluid pathway 128.

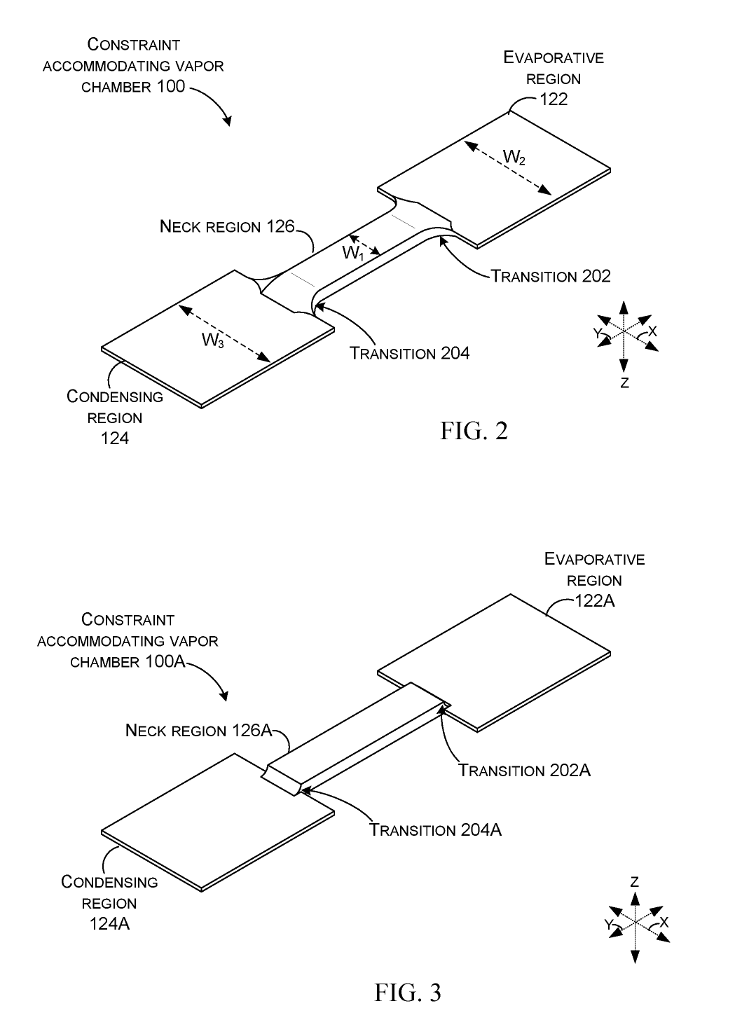

FIG. 2 shows another view of constraint-accommodating vapor chamber 100. In this view, the constrained width W₁ of the neck region 126 is shown relative to the wider widths W₂ and W₃ of the evaporative region 122 and the condensing region 124. In this configuration, a transition area 202 fluidly couples the evaporative region 122 to the neck region 126 and a transition area 204 fluidly couples the neck region 126 to the condensing region 124. In this case, the transition areas 202 and 204 include simultaneous tapers in two reference directions between the adjacent regions. For instance, transition area 202 tapers in the x-reference direction (e.g., tapered transition width) from the wider evaporative region 122 to the narrower neck region 126 while simultaneously tapering in the z-reference direction (e.g., tapered transition height) from the relatively flatter evaporative region to the relatively thicker neck region. Transition area 204 provides similar simultaneous tapering between the neck region 126 and the condensing region 124. Such tapering can avoid reduced cross-sectional areas that can lead to fluid blockage.

FIG. 3 shows an alternative constraint-accommodating vapor chamber 100A. In this case, transition areas 202A and 204A taper in a single dimension (z-reference direction) between the evaporative region 122A and the neck region 126A and between the neck region and the condensing region 124A.

FIGS. 4A and 4B show opposing views of an alternative constraint-accommodating vapor chamber 100B. In this case, evaporative region 122B and condensing region 124B are each planar, but the planes are not parallel to one another. In still other implementations, the evaporative region 122B and condensing region 124B can be planar and parallel, but not co-extensive (e.g., they can be offset).

In the illustrated implementation, the evaporative region 122B and the condensing region 124B define an angle a therebetween. In this configuration, the evaporative region 122B and the condensing region 124B are oriented at right angles to one another (e.g., angle a is 90 degrees). In other cases, the angle can be any oblique angle. In the present configuration, the neck region 126B bends (e.g., is curvilinear) to fluidly couple the evaporative region 122B and the condensing region 124B while maintaining a thickness or height T₁ that is greater than thicknesses T₂ and T₃ of the evaporative region 1228 and the condensing region 124B, respectively. The increased thickness of the neck region can maintain fluid flow and hence thermal transfer within the constraint-accommodating vapor chamber 100B.

FIG. 5 shows another constraint-accommodating vapor chamber 100C that may be employed in a curved housing, such as may be encountered in a wearable device, such as a smart watch or smart glasses/goggles. In this case, evaporative region 122C is positioned over and in heat receiving relation to processor 116C and neck region 126C winds around a constrained space caused by battery 118C. For instance, with respect to the xy-reference plane the neck region is straight at 502 and 504 and bent at 506. Stated another way, sections 502 and 504 can be straight sections and section 506 can be a bent section that connects the straight sections. Simultaneously, neck region 126C can bend from one side of the reference plane to another to accommodate additional constraints. The neck region is narrower but thicker/taller than the evaporative region 122C and the condensing region 124C as represented by thicknesses T₁, T₂, and T₃. In this case, the thickness T₁ of the neck region 126C can be achieved by expanding downward into the space occupied by the processor 116C (under the evaporative region 122C).

In this example, the evaporative region 122C is generally planar to promote efficient thermal transfer from the processor 116C. The condensing region 124C is non-planar to accommodate convective passageways 508 that can create a chimney effect through the condensing region to create effective heat transferring relation from the evaporative region to the heat sink 120C. The neck region 126C can have both linear portions and curvilinear portions to accommodate space constraints associated with the evaporative region and the condensing region.

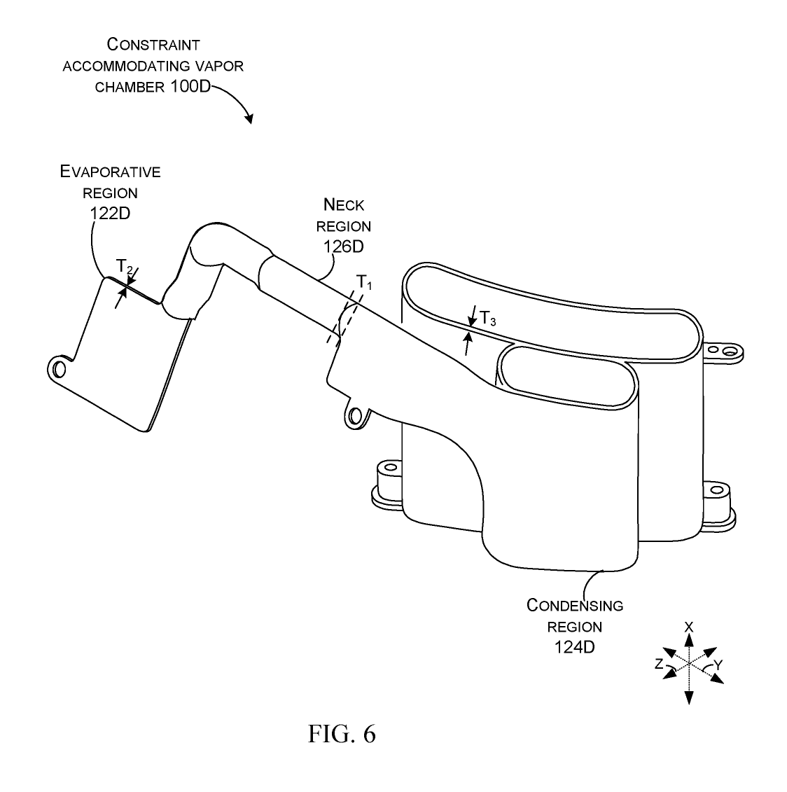

FIG. 6 shows another constraint-accommodating vapor chamber 100D that is similar to constraint-accommodating vapor chamber 100C of FIG. 5. However, in this case, the neck region 126D is curved or arched rather than flat. In this example, the thickness T₁ of the neck region is somewhat difficult to visualize but is represented between dotted lines at the top and bottom of the arch of the neck region. The thickness T₁ can be sufficiently greater than thicknesses T₂, and T₃ of the evaporative region 122D and the condensing region 124D to maintain fluid flow.

Note also, that the cross-sectional area of the neck region 126D can be increased by increasing the height of the neck region to maintain fluid flow along the fluid pathway 128. This cross-sectional area of the neck region may still be less than the cross-sectional areas of the evaporative region 122D and/or the condensing region 124D and provide adequate fluid flow. Alternatively, the cross-sectional areas of the three regions may be equal. In still other implementations, the cross-sectional area of the neck region may be greater than the cross-sectional areas of the evaporative region and/or the condensing region.

Constraint accommodating vapor chambers can be made from various metals. Alternatively or additionally, other thermally conductive materials, such as composites can be employed. The constraint accommodating vapor chambers can be produced utilizing various manufacturing techniques. For instance, major surfaces (e.g., top and bottom) can be formed, such as by 3D printing, forming and drawing, etc. For instance, a sheet metal piece can be formed or drawn at different depths to form the deeper necked region. Wicking/capillary features can be produced from any combination of etching, cutting, forming, sintering, weave or other feature soldered into place. In another case, the top and bottom can be machined from stock material. Once formed, the top and bottom can be glued or welded together with the wick/capillary features sandwiched between.

The present constraint-accommodating vapor chamber concepts can be utilized with various types of devices, such as computing devices that can include but are not limited to notebook computers, tablet type computers, smart phones, wearable smart devices, gaming devices, entertainment consoles, and/or other developing or yet to be developed types of devices. As used herein, a computing device can be any type of device that has some amount of processing and/or storage capacity. A mobile computing device can be any computing device that is intended to be readily transported by a user.

### ADDITIONAL EXAMPLES

Various device examples are described above. Additional examples are described below. One example includes a device comprising a housing defining opposing major surfaces that are parallel to a plane interposed between and a heat generating component positioned in the housing on the plane. The device also comprises an intervening component extending across the plane and a constraint-accommodating vapor chamber positioned on the plane and comprising an evaporative region positioned proximate to the heat generating component and a condensing region positioned proximate to the heat sink and a neck region interposed between the evaporative region and the condensing region and providing a fluid pathway between the evaporative region and the condensing region, the neck region having a width that is constrained by the intervening component and a height that is greater than a height of the evaporative region and the condensing region, the greater height countering the constrained width to maintain the fluid pathway.

Another example can include any of the above and/or below examples where the housing comprises a bucket that defines a first of the opposing major surfaces and a display that defines a second of the opposing major surfaces.

Another example can include any of the above and/or below examples where the housing is curved.

Another example can include any of the above and/or below examples where the heat generating component comprises a processor that is positioned in heat transferring relation to the evaporative region.

Another example can include any of the above and/or below examples where the heat sink comprises the housing.

Another example can include any of the above and/or below examples where the intervening component comprises a battery.

Another example can include any of the above and/or below examples where the neck region is straight, or wherein the neck region is curvilinear, or wherein the neck region comprises two straight sections coupled by a bend.

Another example can include any of the above and/or below examples where a cross-sectional area of the neck region is equal to a cross-sectional area of the evaporative region.

Another example can include any of the above and/or below examples where a cross-sectional area of the neck region is greater than a cross-sectional area of the evaporative region.

Another example can include any of the above and/or below examples where the neck region comprises a tapered transition width between the evaporative region and the neck region.

Another example can include any of the above and/or below examples where the neck region comprises a tapered transition height between the evaporative region and the neck region.

Another example can include any of the above and/or below examples where the neck region comprises both a tapered transition height between the evaporative region and the neck region and a tapered transition width between the evaporative region and the neck region.

Another example includes a vapor chamber, comprising an evaporative region and a condensing region that are connected by a neck region that facilitates fluid flow along a fluid pathway, the neck region having a lesser width and a greater height when viewed transverse the fluid pathway than both the evaporative region and condensing region.

Another example can include any of the above and/or below examples where the evaporative region, the neck region, and the condensing region lie in a single plane.

Another example can include any of the above and/or below examples where the evaporative region lies in a first plane and the condensing region lies in a second plane and the neck region extends between the first plane and the second plane.

Another example can include any of the above and/or below examples where the first plane is parallel to, but not co-extensive with the second plane.

Another example can include any of the above and/or below examples where the first plane forms an oblique angle or right angle relative to the second plane.

Another example includes a device comprising a processor and a vapor chamber comprising an evaporative region positioned in heat receiving relation to the processor, the vapor chamber further comprising a neck region that facilitates fluid flow along a fluid pathway from the evaporative region to a cooling region, the neck region having a taller cross-sectional profile when viewed transverse the fluid pathway than both the evaporative region and condensing region.

Another example can include any of the above and/or below examples where the neck region comprises linear sides that define the taller cross-sectional profile.

Another example can include any of the above and/or below examples where the neck region comprises curvilinear sides that define the taller cross-sectional profile.

### Conclusion

Although techniques, methods, devices, systems, etc., pertaining to constraint-accommodating vapor chambers are described in language specific to structural features and/or methodological acts, it is to be understood that the subject matter defined in the appended claims is not necessarily limited to the specific features or acts described. Rather, the specific features and acts are disclosed as exemplary forms of implementing the claimed methods, devices, systems, etc.

1. A device, comprising:
a housing defining opposing major surfaces that are parallel to a plane interposed between;
a heat generating component positioned in the housing on the plane;
a heat sink positioned in the housing on the plane and spaced away from the heat generating component;
an intervening component extending across the plane; and,
a constraint-accommodating vapor chamber positioned on the plane and comprising an evaporative region positioned proximate to the heat generating component and a condensing region positioned proximate to the heat sink and a neck region interposed between the evaporative region and the condensing region and providing a fluid pathway between the evaporative region and the condensing region, the neck region having a width that is constrained by the intervening component and a height that is greater than a height of the evaporative region and the condensing region, the greater height countering the constrained width to maintain the fluid pathway.

2. The device of claim 1, wherein the housing comprises a bucket that defines a first of the opposing major surfaces and a display that defines a second of the opposing major surfaces.

3. The device of claim 1, wherein the housing is curved.

4. The device of claim 1, wherein the heat generating component comprises a processor that is positioned in heat transferring relation to the evaporative region.

5. The device of claim 1, wherein the heat sink comprises the housing.

6. The device of claim 1, wherein the intervening component comprises a battery.

7. The device of claim 1, wherein the neck region is straight, or wherein the neck region is curvilinear, or wherein the neck region comprises two straight sections coupled by a bend.

8. The device of claim 1, wherein a cross-sectional area of the neck region is equal to a cross-sectional area of the evaporative region.

9. The device of claim 1, wherein a cross-sectional area of the neck region is greater than a cross-sectional area of the evaporative region.

10. The device of claim 1, wherein the neck region comprises a tapered transition width between the evaporative region and the neck region.

11. The device of claim 1, wherein the neck region comprises a tapered transition height between the evaporative region and the neck region.

12. The device of claim 1, wherein the neck region comprises both a tapered transition height between the evaporative region and the neck region and a tapered transition width between the evaporative region and the neck region.

13. A vapor chamber, comprising:
an evaporative region and a condensing region that are connected by a neck region that facilitates fluid flow along a fluid pathway, the neck region having a lesser width and a greater height when viewed transverse the fluid pathway than both the evaporative region and condensing region.

14. The vapor chamber of claim 13, wherein the evaporative region, the neck region, and the condensing region lie in a single plane.

15. The vapor chamber of claim 13, wherein the evaporative region lies in a first plane and the condensing region lies in a second plane and the neck region extends between the first plane and the second plane.

16. The vapor chamber of claim 15, wherein the first plane is parallel to, but not co-extensive with the second plane.

17. The vapor chamber of claim 15, wherein the first plane forms an oblique angle or right angle relative to the second plane.

18. A device, comprising:
a processor; and,
a vapor chamber comprising an evaporative region positioned in heat receiving relation to the processor, the vapor chamber further comprising a neck region that facilitates fluid flow along a fluid pathway from the evaporative region to a condensing region, the neck region having a taller cross-sectional profile when viewed transverse the fluid pathway than both the evaporative region and the condensing region.

19. The device of claim 18, wherein the neck region comprises linear sides that define the taller cross-sectional profile.

20. The device of claim 18, wherein the neck region comprises curvilinear sides that define the taller cross-sectional profile.
